(19) United States
(12) Patent Application Publication
(10) Pub. No.: US 2026/0247592 A1
(43) Pub. Date: Aug. 20, 2026

(54) ELECTROMAGNETIC INTERFERENCE AND RADIO-FREQUENCY INTERFERENCE BARRIER SYSTEMS FOR ENCLOSURES AND ROOMS

(71) Applicant: Scott Christopher Stone, Lansdale, PA (US)

(72) Inventor: Scott Christopher Stone, Lansdale, PA (US)

(21) Appl. No.: 19/541,810

(22) Filed: Feb. 17, 2026

Related U.S. Application Data
(60) Provisional application No. 63/758,765, filed on Feb. 14, 2025.

(51) Int. Cl. H05K 9/00

(52) U.S. Cl. CPC H05K 9/0071

(57) ABSTRACT

An electromagnetic interference, radio-frequency interference, and acoustic interference sealed barrier system for enclosures and rooms is provided. The barrier system embodies a frame portion and a leaf portion movable between an open condition and a closed condition. Along an inner periphery of the frame portion is one or more continuous compressible gaskets while on the opposing inner outer periphery of the jamb portion is a complimentary continuous gasket coupler that urges deformation of the compressible gasket when the closed condition is moved to a locked engagement. The locked engagement may be formed by complimentary electromagnetic elements on the frame and leaf portions so that when a power source is selectively activated the complimentary electromagnetic elements magnetically attract, forming the locked engagement.

### CROSS REFERENCE TO RELATED APPLICATION

This application claims the benefit of priority of U.S. provisional application number 63/758,765, filed 02/14/2025, the contents of which are herein incorporated by reference.

### BACKGROUND OF THE SUBJECT DISCLOSURE

The present subject disclosure relates to barrier systems and, more particularly, to a door system configured as a barrier that prevents breach or interference by radio frequencies, electromagnetic waves, and/or acoustic waves.

The prior art has heretofore tackled the problem of providing leak-proof high-performance electromagnetic interference / radio frequency interference (EMI/RFI) shielding seals in specialized enclosures and rooms through the following means: (1) finger-stock and knife edge door guards, wherein finger-stock gaskets feature "fingers" that deform or compress to engage the knife edge portion creating an electrical seal. Typically, the knife edge portion provides a sharp metal edge on the door perimeter that inserts into the finger-stock, forming the shield as the fingers deform and engage the knife edge portions; and (2) a bladder system wherein inflatable, conductive elastomer or fabric-over-foam bladder is attached to a door or opening. Upon inflation, it creates a continuous conductive seal against the frame, closing any potential gaps.

Unfortunately, the finger-stock and knife edge method is a quickly damaged consumable item, due to the repeated deformation required to form a seal, particularly how they are original shaped and thus how they deform to form a seal. The finger-stock and knife edge method also requires specialized knowledge to maintain and service, including the use of flat tools (e.g., putty knife). Finger-stock and knife edge methods additionally require great force to operate its geared latching mechanism which some users are unable to provide. A disadvantage of the bladder system requires use of a compressor and sealed system demanding specialized service and parts to maintain, wherein lack of specialized maintenance can cause minor component failure which renders the entire system unusable.

In sum, specialized parts and maintenance skills required to keep prior art systems running makes them difficult to sustain. This is in addition to the notion that the prior art systems are not user friendly as not everyone can operate them.

As can be seen, there is a need for an electromagnetic interference, radio-frequency interference, and acoustic sealed barrier system for enclosures and rooms adapted to be more serviceable and easier to operate than existing methods.

### SUMMARY OF THE SUBJECT DISCLOSURE

The door system embodied by the subject disclosure provides magnets configured to prevent breach by EMI, RFI, and/or acoustic waves, wherein the door system is adapted to operate easier than the prior art as well as provides an entirely novel sealing engagement so that gaskets are less consumable (e.g., portions that undergo deformation, stress and strain during the sealing process are configured differently and so less likely in need of replacement, relative to the prior art) and offer maintenance surfaces that are more accessible during cleaning, as well as the potential for a tighter seal without the requirement of immoderate physical exertion.

In one aspect of the subject disclosure, a barrier system for an enclosure, wherein the barrier system includes the following: a frame portion along a perimeter of an access opening to the enclosure; a leaf portion moveable relative to the frame portion so as to be positioned between an open condition and a closed condition preventing access to the access opening; one or more compressible gaskets extending continuously along a perimetral surface of the frame portion; for each compressible gasket, a gasket coupler extending continuously along a perimetral surface of the leaf portion; a plurality of first electromagnetic elements mounted to the frame portion; a plurality of second electromagnetic elements mounted to the leaf portion so that said pluralities of electromagnetic elements align in the closed condition, and wherein a selective activation of the plurality of first electromagnetic elements forms a locked engagement between the frame and leaf portions so that each gasket coupler deforms a respective compressible gasket whereby electromagnetic and radio frequency interference is prevented from entering the enclosure.

In another aspect of the subject disclosure, the barrier system further includes wherein the plurality of first electromagnetic elements are selectively activated by a power source, thereby enabling the formation of the locked engagement, and wherein the perimetral surfaces of the frame and leaf portions, respectively, are lateral surface, and wherein said pluralities of electromagnetic elements are mounted to radial surface of the respective frame and leaf portions.

In yet another aspect of the subject disclosure, a barrier system for an enclosure includes the following: a locked engagement between a frame portion and leaf portion positioned and sized, in combination, to close off an access opening to the enclosure; and wherein the locked engagement is formed through a selective activation of one or more first electromagnetic elements operatively associated with the frame portion and complimentary second electromagnetic elements operatively associated with the leaf portion, whereby the locked engagement urges deformation of a compressible seal gasket along an inner periphery of the frame portion to deform so as to prevent electromagnetic and radio frequency interference is prevented from entering the enclosure.

These and other features, aspects and advantages of the present subject disclosure will become better understood with reference to the following drawings, description and claims.

### BRIEF DESCRIPTION OF THE DRAWINGS

FIG. 1 is a schematic view of an exemplary embodiment of frame portion 12 of a barrier system 100 of the subject disclosure, wherein an inner perimeter of the frame portion 12, or frame jamb 16, engages an outer periphery of a leaf portion (or leaf jamb 17, not shown in FIG. 1, but shown in FIG. 5).

FIG. 2 is a schematic view of an exemplary embodiment of a momentary interruption switch 11 of the subject disclosure.

FIG. 3 is a detailed top plan section view of an exemplary embodiment of frame jamb 16 of frame portion 12 the subject disclosure, indicated by box 16 of FIG. 1, illustrating the compressible, deformable seal gasket 20 that extends continuously along an entirety of the inner periphery of the frame jamb 16 of frame portion 12.

FIG. 4 is a detailed top plan section view of an exemplary embodiment of the leaf jamb 17 of the leaf portion 13 of the subject disclosure, indicated by box 17 of FIG. 5, illustrating the gasket coupler 21 that extends continuously along an entirety of the outer periphery of the leaf jamb 17 of the leaf portion 13 so as to align with its counterpart seal gasket 20 of the frame jamb 16.

FIG. 5 is a schematic view of an exemplary embodiment of a leaf portion 13 of the barrier system 100 of the subject disclosure.

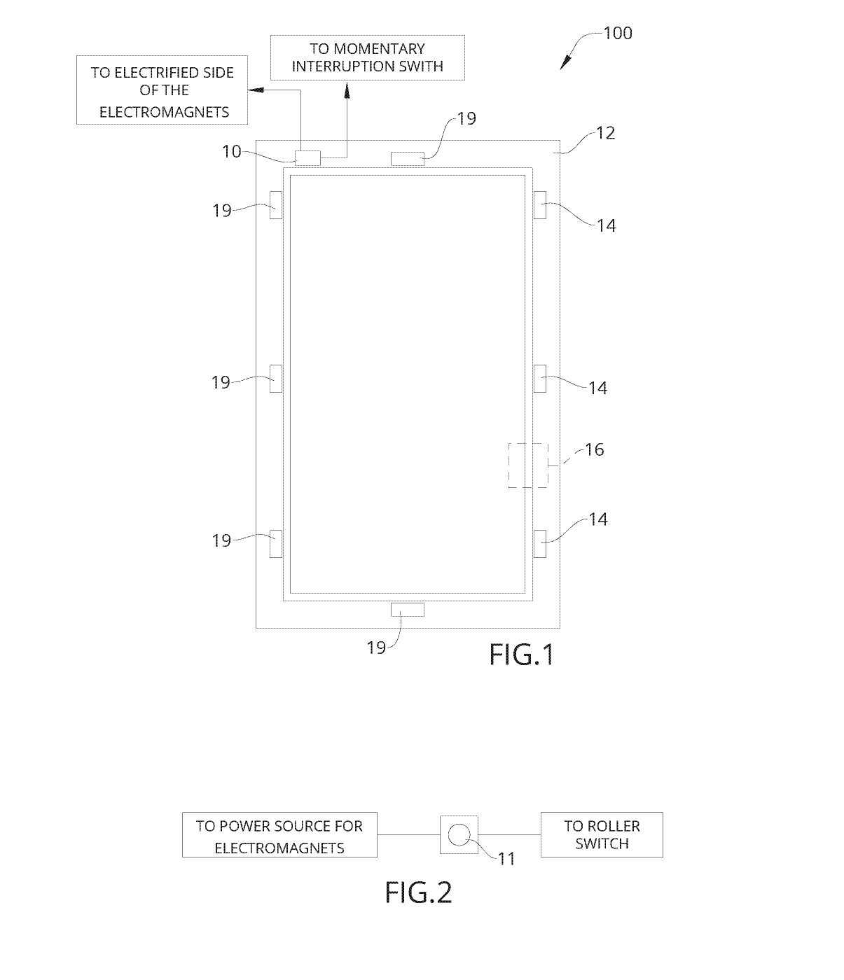

### DETAILED DESCRIPTION OF THE SUBJECT DISCLOSURE

The following detailed description is of the best currently contemplated modes of carrying out exemplary embodiments of the subject disclosure. The description is not to be taken in a limiting sense but is made merely for the purpose of illustrating the general principles of the subject disclosure, since the scope of the subject disclosure is best defined by the appended claims.

Broadly, an embodiment of the present subject disclosure provides an electromagnetic interference, radio-frequency interference, and acoustic sealed barrier system for enclosures and rooms.

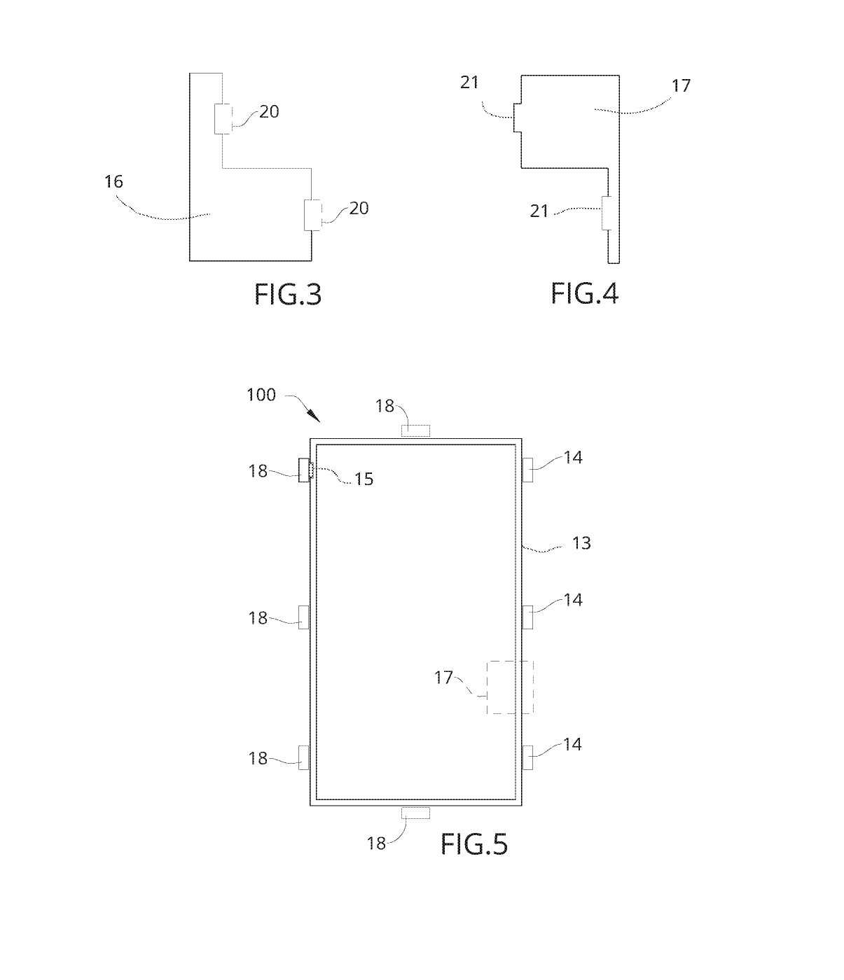

Referring to the Figures, a barrier system 100 for enclosures and rooms adapted to seal such enclosures and rooms from electromagnetic interference, radio-frequency interference, and acoustic waves include a frame portion 12 and a leaf portion 13 that move out of plane of each other by way of moving points 14. The moving points 14 may be but are not necessarily pivot points as long as the moving points enable the out of plane relative movement so that the barrier system 10 is movable between an open condition and a closed condition sealing the entirety of the perimeters (or jambs 16 and 17, respectively) of the frame portion 12 and the leaf portion 13 that physically engage. The jambs 16 and 17 provide a protruding compressions gasket 20 and gasket coupler 21, respectively, so that in the closed condition the gasket coupler urges deformation against the gasket coupler 21. In some embodiments, the gasket coupler 21 may be a rigid material, such as brass, cooper, or the like that has electromagnetic, radio frequency, and/or acoustic interference properties. As shown in FIGS. 3 and 4, the complementary compressions gaskets 20 and gasket couplers 21 may occupy offset lateral surfaces of the jambs 16 and 17, respectively (lateral surface of a jamb being the surface that faces the opposing jamb).

In operation, first switch 11 may be electrically connected to a power source and the frame portion 12. Frame portion 12 provides a plurality of first electromagnetic elements 19 which may be surface mounted intermittently along an outward-facing or radial surface (orthogonal the lateral surface). Spaced along the radial surface of the leaf portion 13 may be second electromagnetic elements 18. In some embodiments, brackets 15 enable an entirety of each of the second electromagnetic elements 18 to project beyond the outer perimeter/jamb 17 of the leaf portion 13. In embodiments, the location and mounting methods may vary as long as the complementary first and second electromagnetic elements 19 and 18 align so that when the first switch 11 is moved to an activated state the first electromagnetic elements 19 are energized or powered so that the first and second electromagnetic elements 19 and 18 are magnetically attracted so that the lateral surface of the respective jambs 16 and 17, respectively, are urged together in a locked engagement when the barrier system 100 is in the closed condition. This locked engagement, in turn, urges the complementary compression seal gaskets to deform into their respective gasket coupler 21, forming an electromagnetic, radio frequency, and/or acoustic wave shield between the frame portion 12 and the leaf portion 13.

In embodiments, the first switch 11 may be activated by compression seal gasket 20 when the frame portion 12 and the leaf portion 13 are in the closed condition. When the frame portion 12 and the leaf portion 13, which in some embodiments may or may not be conductive, are together, the tight bond is caused by the first switch 11 squeezing a roller switch 10, creating the electromagnetic, radio frequency, acoustic interference shield/seal.

The electromagnetic locks, enabled by the magnetic attraction between electromagnetic elements 19 and 18, are selectively controlled/powered by the power source. When the door is closed, these electromagnetic locks may be activated by a roller switch 10 which will pull the door tight making sure that the compressible EMI/RFI/acoustic gasket 20 does not allow any leaks. When one desires to open the barrier, a user will operate the first switch 11 which will deactivate the magnetic pull of the electromagnetic locks momentarily for operation of the door.

A method of making the subject disclosure may include a manufacturer making the door (e.g., leaf portion) and frame portion and on one of the two surfaces (where they mate) include an RF gasket, acoustic gasket, or other compression seal gasket 20 between the door and frame 12. Then one would mount electromagnetic locks using mechanical fastening to the door and wire the electromagnetic locks appropriately based on the local electrical phasing. Roller switch 10 may be mounted to frame 12 to contact the door leaf 13 and activate the magnets, button switch 11 may be mounted to the side frame 12 or nearby to momentarily interrupt the power of the electromagnetic switch causing the release for door operation. Varying mounting location and/or quantity of the electromagnetic locks or switches could provide identical or similar function.

To use the subject disclosure, a user could change out an existing door for a door using the described RF and/or acoustic sealing method. Assuming measurements are properly taken it would be a direct replacement. This could also be installed into new door openings. When installed the door would be closed to activate a seal, to open a button is pressed and the door is pulled open, and one could pass through the opening.

Additionally, while the subject disclosure is to be used to protect information/transmitting and/or be used for noise pollution, the subject disclosure could be used in the medical field to protect patients. The tight seal could also be used for airtight seal as well or any other gasketed openings that require a tight compressive force to seal.

As used in this application, the term "about" or "approximately" refers to a range of values within plus or minus 10% of the specified number. And the term “substantially” refers to up to 80% or more of an entirety. Recitation of ranges of values herein are not intended to be limiting, referring instead individually to any and all values falling within the range, unless otherwise indicated, and each separate value within such a range is incorporated into the specification as if it were individually recited herein.

For purposes of this disclosure, the term “aligned” means parallel, substantially parallel, or forming an angle of less than 35.0 degrees. For purposes of this disclosure, the term “transverse” means perpendicular, substantially perpendicular, or forming an angle between 55.0 and 125.0 degrees. Also, for purposes of this disclosure, the term “length” means the longest dimension of an object. Also, for purposes of this disclosure, the term “width” means the dimension of an object from side to side. For the purposes of this disclosure, the term “above” generally means superjacent, substantially superjacent, or higher than another object although not directly overlying the object. Further, for purposes of this disclosure, the term “mechanical communication” generally refers to components being in direct physical contact with each other or being in indirect physical contact with each other where movement of one component affect the position of the other.

The use of any and all examples, or exemplary language (“e.g.,” “such as,” or the like) provided herein, is intended merely to better illuminate the embodiments and does not pose a limitation on the scope of the embodiments or the claims. No language in the specification should be construed as indicating any unclaimed element as essential to the practice of the disclosed embodiments.

In the following description, it is understood that terms such as “first,” “second,” “top,” “bottom,” “up,” “down,” and the like, are words of convenience and are not to be construed as limiting terms unless specifically stated to the contrary.

It should be understood, of course, that the foregoing relates to exemplary embodiments of the subject disclosure and that modifications may be made without departing from the spirit and scope of the subject disclosure as set forth in the following claims.

What is claimed is:

1. A barrier system for an enclosure, wherein the barrier system comprises:
a frame portion along a perimeter of an access opening to the enclosure;
a leaf portion moveable relative to the frame portion so as to be positioned between an open condition and a closed condition preventing access to the access opening;
one or more compressible gaskets extending continuously along a perimetral surface of the frame portion;
for each compressible gasket, a gasket coupler extending continuously along a perimetral surface of the leaf portion;
a plurality of first electromagnetic elements mounted to the frame portion;
a plurality of second electromagnetic elements mounted to the leaf portion so that said pluralities of electromagnetic elements align in the closed condition, and
wherein a selective activation of the plurality of first electromagnetic elements forms a locked engagement between the frame and leaf portions so that each gasket coupler deforms a respective compressible gasket whereby electromagnetic and radio frequency interference is prevented from entering the enclosure.

2. The barrier system of claim 1, further comprising a power source electrically coupled to either of the plurality the first electromagnetic elements or the plurality of second electromagnetic elements so as to form the locked engagement through electrifying either by selectively activating a switch.

3. The barrier system of claim 1, wherein the perimetral surfaces of the frame and leaf portions, respectively, are lateral surface, and wherein said pluralities of electromagnetic elements are mounted to radial surface of the respective frame and leaf portions.

4. A barrier system for an enclosure, wherein the barrier system comprises:
a locked engagement between a frame portion and leaf portion positioned and sized, in combination, to close off an access opening to the enclosure; and
wherein the locked engagement is formed through a selective activation of one or more first electromagnetic elements operatively associated with the frame portion and complimentary second electromagnetic elements operatively associated with the leaf portion, whereby the locked engagement urges deformation of a compressible seal gasket along an inner periphery of the frame portion to deform so as to prevent electromagnetic and radio frequency interference is prevented from entering the enclosure.
